(19) United States
(12) Patent Application Publication
(10) Pub. No.: US 2026/0196801 A1
(43) Pub. Date: Jul. 9, 2026

(54) Multichip Module

(71) Applicant: NTT, Inc., Tokyo (JP)

(72) Inventors: Kiyofumi Kikuchi, Musashino-shi, Tokyo (JP); Ken Tsuzuki, Musashino-shi, Tokyo (JP); Takashi Yamada, Musashino-shi, Tokyo (JP); Masayuki Takahashi, Musashino-shi, Tokyo (JP)

(21) Appl. No.: 18/861,508

(22) PCT Filed: May 6, 2022
(86) PCT No.: PCT/JP2022/019601

§ 371 Date: Oct. 29, 2024

(51) Int. Cl. H01S 5/024; H01S 5/02208

(52) U.S. Cl. CPC H01S 5/02469; H01S 5/02208

(57) ABSTRACT

Provided is a multi-chip optical module in which a plurality of IC chips mounted on one substrate are packaged, the multi-chip optical module including: a lid component that forms an accommodation space for accommodating the plurality of IC chips together with the substrate and has protrusions protruding toward each of the IC chips; and adhesive layers formed between the protrusions and the IC chips, in which protrusion lengths of the protrusions vary according to heights of the protrusions with respect to the substrate.

### TECHNICAL FIELD

The present disclosure relates to a multi-chip module.

### BACKGROUND ART

Against the background of an increase in demand for communication, further increase in capacity of a communication network has been studied. In particular, there is an increasing demand for large capacity for optical communication. Furthermore, there is a strong demand for miniaturization of optical modules used in optical communications in order to improve the bit rate per unit volume of communication equipment and reduce power consumption. A multi-chip module in which a plurality of types of integrated circuits (ICs) and optical chips are mounted on one chip substrate is effective for miniaturization of the optical modules. Such a multi-chip module is described in Patent Literature 1, for example. The optical integrated circuit type optical device described in Patent Literature 1 is configured by accommodating a planar substrate optical integrated circuit and an electric circuit in one package.

### CITATION LIST

### Patent Literature

Patent Literature 1: JP 2017-223742 A

### SUMMARY OF INVENTION

However, it is known that IC chips such as optical chips generate heat during operation. In a case where a plurality of IC chips are integrated on one substrate, the thermal density of the module increases, resulting in higher operating temperatures. Since increasing the temperature of the module impairs the reliability of the IC chip, there is a need to enhance this heat dissipation. Here, the heat dissipation of the IC chip will be described.

FIG. 1 is a view illustrating a cross section of a known multi-chip optical module 1. The multi-chip optical module 1 includes a substrate 11, IC chips 21A, 21B, and 21C mounted on one surface (mounting surface) of the substrate 11, and a lid component 13 that accommodates the IC chips 21A, 21B, and 21C together with the substrate 11. The IC chips 21A, 21B, and 21C are mounted by bumps 22, and external terminals 12 are formed on the back surface of the mounting surface of the substrate 11. In the multi-chip optical module 1, the plurality of integrated IC chips 21A, 21B, and 21C have different heights. Each of the IC chips 21A, 21B, and 21C is connected to the metal lid component 13 with a thermally conductive adhesive. With such a configuration, the IC chips 21A, 21B, and 21C are thermally and mechanically connected to the lid component 13.

An upper surface 13a of the lid component 13 has a constant thickness. In addition, the heights of the IC chips 21A, 21B, and 21C are the lowest in the IC chip 21A, and then increase in the order of the IC chip 21B and the IC chip 21C. Therefore, a thickness h1 of an adhesive layer 14 on the IC chip 21A is the thickest, and a thickness h2 of the adhesive layer 14 on the IC chip 21B and a thickness h3 of the adhesive layer 14 on the IC chip 21B become thinner in that order. Since a thermally conductive adhesive has high thermal resistance, it is known that it becomes difficult for heat to be dissipated when the thickness thereof is thick. In the example illustrated in FIG. 1, it is most difficult for heat to be dissipated in the adhesive layer 14 on the IC chip 21A, the temperature rises, and the reliability of the entire multi-chip optical module 1 is impaired.

An aspect of the present invention has been made in view of the above points, and relates to a multichip module in which a plurality of chip components having different heights are integrated, which has high heat dissipation, and enhances reliability while suppressing temperature rise.

In order to achieve the above object, according to one aspect of the present invention, there is provided a multichip module in which a plurality of chip components mounted on one substrate are packaged, the multichip module including: a lid component that forms an accommodation space for accommodating the plurality of chip components together with the substrate and has protrusions protruding toward each of the chip components; and first adhesive layers formed between the protrusions and the chip components, in which protrusion lengths of the protrusions vary according to heights of the chip components with respect to the substrate.

According to the above aspect, in the multichip module in which the plurality of chip components having different heights are integrated, the heat dissipation is high, and the reliability can be enhanced while suppressing temperature rise.

### BRIEF DESCRIPTION OF DRAWINGS

FIG. 1 is a view illustrating a cross section of a known multi-chip optical module.

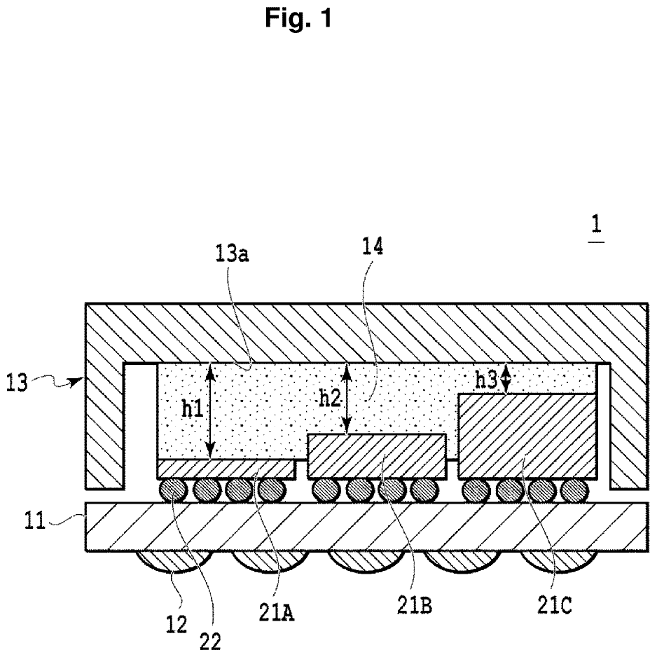

FIG. 2 is a view illustrating a cross section of a multi-chip optical module according to a first embodiment.

FIG. 3 is a view illustrating a cross section of a multi-chip optical module according to a second embodiment.

FIG. 4 is a view illustrating a cross section of a multi-chip optical module according to a third embodiment.

FIG. 5 is a view illustrating a cross section of a multi-chip optical module according to a fourth embodiment.

FIG. 6 is a view illustrating a cross section of a multi-chip optical module according to a fifth embodiment.

FIG. 7 is a view illustrating a cross section of a multi-chip optical module according to a sixth embodiment.

FIG. 8 is a view illustrating a cross section of a multi-chip optical module according to a seventh embodiment.

### DESCRIPTION OF EMBODIMENTS

First to seventh embodiments of the present invention will be described below with reference to the drawings. In the drawings, the same members are denoted by the same reference numerals, and the description thereof may be omitted. In addition, the purpose of the drawings is to describe configurations, technical ideas, functions, effects, a positional relationship of each unit, and the like of the first to seventh embodiments. Therefore, the drawings do not limit specific shapes of the multi-chip modules according to the first to seventh embodiments. In addition, the drawings are not limited to those accurately illustrating the aspect ratios and dimensional shapes of the multi-chip modules and the chip components of the first to seventh embodiments. In the first to seventh embodiments, the multi-chip module is configured as a multi-chip optical module in which IC chips of optical devices are integrated.

### First Embodiment

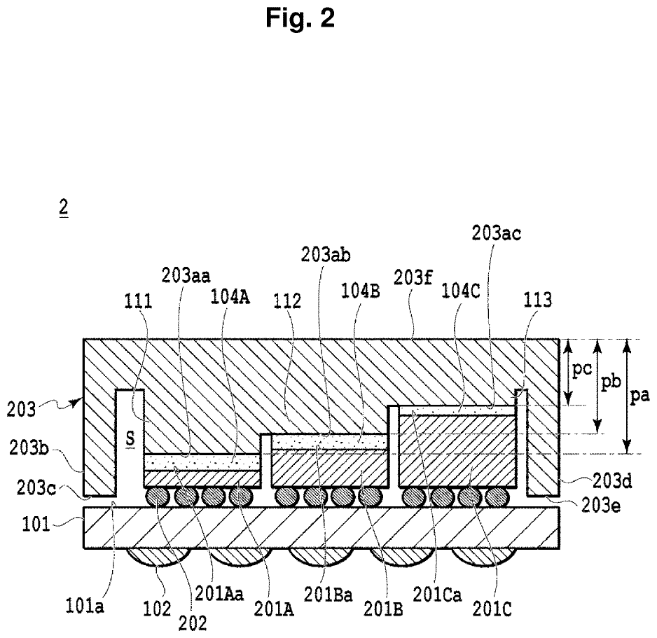

FIG. 2 is a cross-sectional view for describing a multi-chip optical module 2 according to a first embodiment. The multi-chip optical module 2 is configured by packaging a plurality of IC chips 201A, 201B, and 201C which are chip components mounted on one substrate 101. The cross-sectional view illustrates a cross section of the multi-chip optical module 2 cut in the direction in which the IC chips 201A, 201B, and 201C are disposed. The mounting is performed by a bump 202. The substrate 101 includes an external terminal 102 for electrically connecting the IC chips 201A, 201B, and 201C to an external device. Hereinafter, in the present specification, the vertical direction is determined such that a mounting surface 101a of the substrate 101 is mounted below the IC chips 201A, 201B, and 201C, that is, the IC chips 201A, 201B, and 201C are mounted on the mounting surface 101a. Such a vertical direction is determined independently of the direction of gravity.

The IC chips 201A, 201B, and 201C, which are optical devices, are configured by integrating optical elements such as an optical waveguide, an optical modulator, and a semiconductor laser on a single crystal substrate such as silicon or a compound semiconductor. The multi-chip optical module 2 includes a lid component 203 that forms an accommodation space S for accommodating the IC chips 201A, 201B, and 201C together with the substrate 101. The IC chips 201A, 201B, and 201C illustrated in FIG. 2 have different heights, and the height of the IC chip 201A is the lowest and the height of the IC chip 201C is the highest. The accommodation space S only needs to be a space including the IC chips 201A, 201B, and 201C, and there is no need to seal the IC chips 201A, 201B, and 201C.

In addition, the lid component 203 has protrusions 111, 112, and 113 protruding toward the IC chips 201A, 201B, and 201C, respectively. The protrusion lengths of the protrusions 111, 112, and 113 differ depending on the heights of the IC chips 201A, 201B, and 201C with respect to the substrate 101. Further, the multi-chip optical module 2 includes adhesive layers 104A, 104B, and 104C, which are first adhesive layers formed between the protrusions 111, 112, and 113 and the IC chips 201A, 201B, and 201C.

The lid component 203 includes side wall portions 203b and 203d around the protrusions 111, 112 and 113. The side wall portions 203b and 203d form a series of walls. A surface of the side wall portion 203b facing the substrate 101 is referred to as a side wall facing surface 203c, and a surface of the side wall portion 203d facing the substrate 101 is referred to as a side wall facing surface 203e. Further, an upper surface of the IC chip 201A facing the protrusion 111 is referred to as a chip facing surface 201Aa, an upper surface of the IC chip 201B facing the protrusion 112 is referred to as a chip facing surface 201Ba, and an upper surface of the IC chip 201C facing the protrusion 113 is referred to as a chip facing surface 201Ca.

The “heights” of the IC chips 201A, 201B, and 201C refer to distances from the mounting surface 101a to the chip facing surfaces 201Aa, 201Ba, and 201Ca of the IC chips 201A, 201B, and 201C with respect to the substrate 101 (mounting surface 101a). However, the first embodiment is not limited to such a reference, and the heights of the IC chips 201A, 201B, and 201C may be determined with respect to one common surface. Note that the height of the IC chip 201A and the like is equal to the thickness of the IC chip 201A and the like.

As illustrated in FIG. 2, the protrusion lengths of the protrusions 111, 112, and 113 differ depending on the heights of the IC chips 201A, 201B, and 201C with respect to the substrate 101. Here, the “protrusion lengths” refer to lengths from a reference position common to the protrusions 111, 112, and 113 to protruding facing surfaces 203aa, 203ab, and 203ac of the protrusions 111, 112, and 113 facing the IC chips 201A, 201B, and 201C. In the example illustrated in FIG. 2, the protrusion length is determined with respect to an upper surface 203f of the lid component 203. However, the first embodiment is not limited to such an example, and for example, the protrusion length may be determined with respect to any surface of the inner surface of the lid component 203, or may be determined with respect to any surface of the protruding facing surfaces 203aa, 203ab, and 203ac.

As illustrated in FIG. 2, a protrusion length pa of the protrusion 111 on the IC chip 201A having the lowest height is longest, a protrusion length pb of the protrusion 112 on the IC chip 201B having the second highest height is the second longest, and a protrusion length pc of the protrusion 113 on the IC chip 201C having the longest protrusion length is the shortest. Then, the IC chip 201A is fixed to the lid component 203 by the adhesive layer 104A between the chip facing surface 201Aa and the protruding facing surface 203aa. The IC chip 201B is fixed to the lid component 203 by the adhesive layer 104B between the chip facing surface 201Ba and the protruding facing surface 203ab, and the IC chip 201C is fixed to the lid component 203 by the adhesive layer 104C between the chip facing surface 201Ca and the protruding facing surface 203ac. According to such a configuration, the thicknesses of the adhesive layers 104A, 104B, and 104C are made sufficiently thin regardless of the heights of the IC chips 201A, 201B, and 201C, and the heat storage of the adhesive layer is suppressed to prevent temperature rise of the IC chip. Then, it is possible to prevent malfunction or the like due to temperature rise of the IC chip and contribute to enhancing the reliability of the IC chip.

Furthermore, the first embodiment uses the lid component 203 that is at least partially made of a metal material. Examples of such a lid component include those obtained by applying nickel plating to a Kovar material, which is an alloy containing iron, nickel, and cobalt, and those made of a gold tin alloy. Such a lid component 203 has high heat conductivity and high heat dissipation, and can further enhance the effect of suppressing temperature rise of the IC chip.

### Second Embodiment

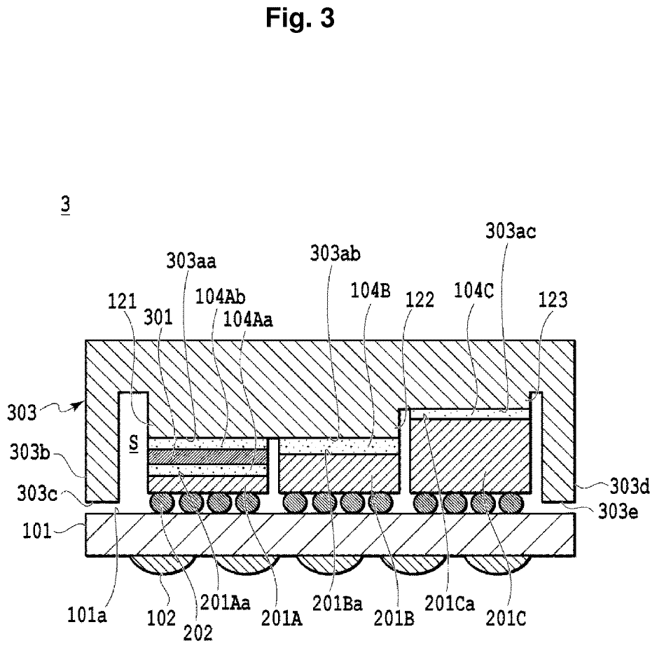

FIG. 3 is a cross-sectional view for describing a multi-chip optical module 3 according to a second embodiment. The multi-chip optical module 3 is a multi-optical module in which a plurality of IC chips 201A, 201B, and 201C mounted on one substrate 101 are packaged. The multi-chip optical module 3 includes a substrate 101 and a lid component 303. The substrate 101 and the lid component 303 are overlapped to form an accommodation space S of the IC chips 201A, 201B, and 201C. The lid component 303 includes protrusions 121, 122, and 123 protruding toward the IC chips 201A, 201B, and 201C, respectively. A protruding facing surface 303aa of the protrusion 121 faces the IC chip 201A, a protruding facing surface 303ab of the protrusion 122 faces the IC chip 201B, and a protruding facing surface 303ac of the protrusion 123 faces the IC chip 201C. A series of side wall portions 303b and 303d are provided around the IC chips 201A, 201B, and 201C. A side wall facing surface 303c of the side wall portion 303b and a side wall facing surface 303e of the side wall portion 303d face the substrate 101.

Among the protrusions 121, 122, and 123, the protrusion 121 is disposed on the IC chip 201A, the protrusion 122 is disposed on the IC chip 201B, and the protrusion 123 is disposed on the IC chip 201C. The lengths of the protrusions 122 and 123 correspond to the heights of the IC chips 201B and 201C, similarly to the first embodiment. That is, the length of the protrusion 122 on the IC chip 201B having a relatively low height is relatively long, and the length of the protrusion 123 on the IC chip 201C having a relatively high height is relatively short.

In the second embodiment, the protrusions 121 and 122 have the same protrusion length and are integrated. However, in the second embodiment, the integrated protrusions 121 and 122 are distinguished using, for example, a surface where a virtual plane passing between the IC chips 201A and 201B and orthogonal to the substrate 101 intersects with the lid component 303 as a boundary. On the other hand, the height of the IC chip 201A is lower than that of the IC chip 201B, and the interval between the chip facing surface 201Aa and the protruding facing surface 303aa is wider than the interval between the chip facing surface 201Ba and the protruding facing surface 303ab. In the second embodiment, adhesive layers 104Aa and 104Ab between the IC chip 201A and the protrusion 121 include a spacer 301. The sum of the thicknesses of the adhesive layers 104Aa and 104Ab including the spacer 301 and the height (thickness) of the IC chip 201A is equal to the sum of the thicknesses of the IC chip 201B and the adhesive layer 104B.

The spacer 301 may be formed using AIN or CuW as a material. Since the spacer 301 has higher processing accuracy than the lid component 303, the thicknesses of the adhesive layers 104Aa and 104Ab can be adjusted with higher accuracy to suppress variations. That is, since the lid component 303 is manufactured by cutting the base material, the dimensional tolerance of the step of the protrusion is about 100 μm. On the other hand, since the spacer 301 is manufactured by cutting the base material and plating, the dimensional tolerance can be suppressed to about 20 μm. According to the second embodiment, it is possible to adjust the thicknesses of the adhesive layers 104Aa and 104Ab on the IC chip 201A with high accuracy and to minimize the thicknesses without providing steps by equalizing the heights of the protrusions 121 and 122.

### Third Embodiment

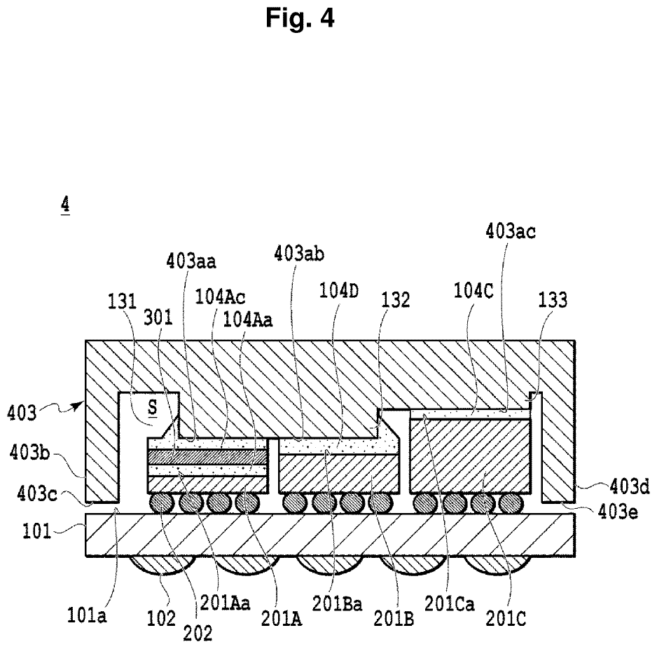

FIG. 4 is a cross-sectional view for describing a multi-chip optical module 4 according to a third embodiment. The multi-chip optical module 4 includes a substrate 101 and a lid component 403. The lid component 403 includes protrusions 131, 132, and 133 protruding toward the IC chips 201A, 201B, and 201C, respectively. A protruding facing surface 403aa of the protrusion 131 faces the IC chip 201A, a protruding facing surface 403ab of the protrusion 132 faces the IC chip 201B, and a protruding facing surface 403ac of the protrusion 133 faces the IC chip 201C. A series of side wall portions 403b and 403d are provided around the IC chips 201A, 201B, and 201C. A side wall facing surface 403c of the side wall portion 403b and a side wall facing surface 403e of the side wall portion 403d face the substrate 101.

In the third embodiment, there is no step between the protrusions 131 and 132, and the protrusions are integrated with each other. Further, a spacer 301 is disposed between the IC chip 201A and the protruding facing surface 403aa, and adhesive layers 104Aa and 104Ac are formed above and below the spacer 301. Further, in the third embodiment, the area of the protruding facing surface 403aa of the protrusion 131 is smaller than the area of the chip facing surface 201Aa, and the area of the protruding facing surface 403ab of the protrusion 132 is smaller than the area of the chip facing surface 201Ba. According to such a configuration, the adhesive on the chip facing surfaces 201Aa and 201Ba protrudes from the protrusions 131 and 132, respectively, to form the adhesive layers 104Ac and 104D having fillets. Therefore, the third embodiment can prevent the adhesive from flowing into the side of the substrate 101. In addition, the adhesive strength between the lid component 403 and the IC chip 201A and the like using the adhesive can be enhanced.

### Fourth Embodiment

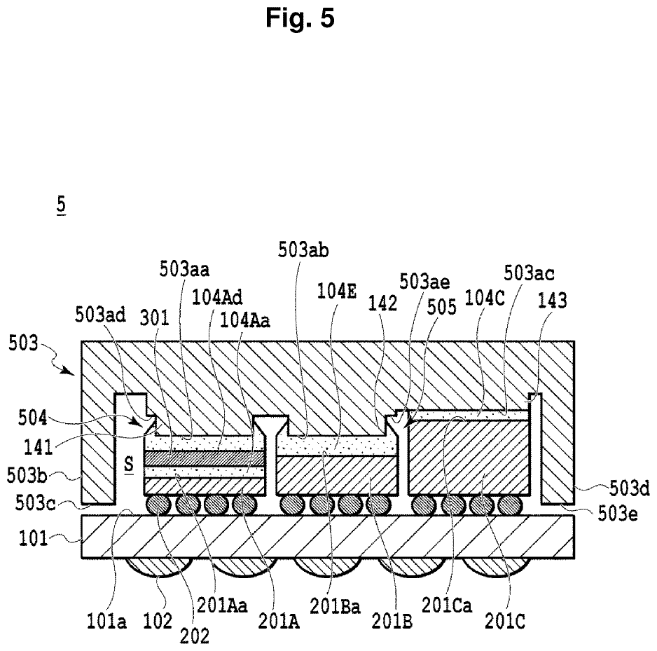

FIG. 5 is a cross-sectional view for describing a multi-chip optical module 5 according to a fourth embodiment. The multi-chip optical module 5 includes a substrate 101 and a lid component 503. The lid component 503 includes protrusions 141, 142, and 143 protruding toward the IC chips 201A, 201B, and 201C, respectively. A protruding facing surface 503aa of the protrusion 141 faces the IC chip 201A, a protruding facing surface 503ab of the protrusion 142 faces the IC chip 201B, and a protruding facing surface 503ac of the protrusion 143 faces the IC chip 201C. A series of side wall portions 503b and 503d are provided around the IC chips 201A, 201B, and 201C. A side wall facing surface 503c of the side wall portion 503b and a side wall facing surface 503e of the side wall portion 503d face the substrate 101. An adhesive layer 104Aa, a spacer 301, and an adhesive layer 104Ad are provided between the protruding facing surface 503aa and the chip facing surface 201Aa.

The fourth embodiment is different from the first embodiment and the like in that the protrusions 141 and 142 each include a stepped portion having a different protrusion length. That is, as illustrated in FIG. 5, the protrusion 141 has a protruding facing surface 503ad having a shorter protrusion length than the protruding facing surface 503aa, in addition to the protruding facing surface 503aa. The protruding facing surfaces 503aa and 503ad form a stepped portion 504. In addition to the protruding facing surface 503ab, the protrusion 142 has a protruding facing surface 503ae having a shorter protrusion length than the protruding facing surface 503ab. The protruding facing surfaces 503ab and 503ae form a stepped portion 505. Furthermore, also in the fourth embodiment, similarly to the third embodiment, the area of the protruding facing surface 503aa is smaller than the area of the chip facing surface 201Aa, and the area of the protruding facing surface 503ab is smaller than the area of the chip facing surface 201Ba.

According to such a fourth embodiment, the adhesive protrudes from the protrusion 141 and flows into the stepped portion 504 to form the adhesive layer 104Ad having a fillet. In addition, the adhesive between the chip facing surface 201Ba and the protruding facing surface 503ab of the IC chip 201B protrudes from the protrusion 142 and flows into the stepped portion 505 to form an adhesive layer 104E having a fillet. Therefore, the adhesive can be prevented from moving toward the substrate 101, and the adhesive strength between the lid component 503 and the IC chip 201A and the like using the adhesive can be enhanced.

### Fifth Embodiment

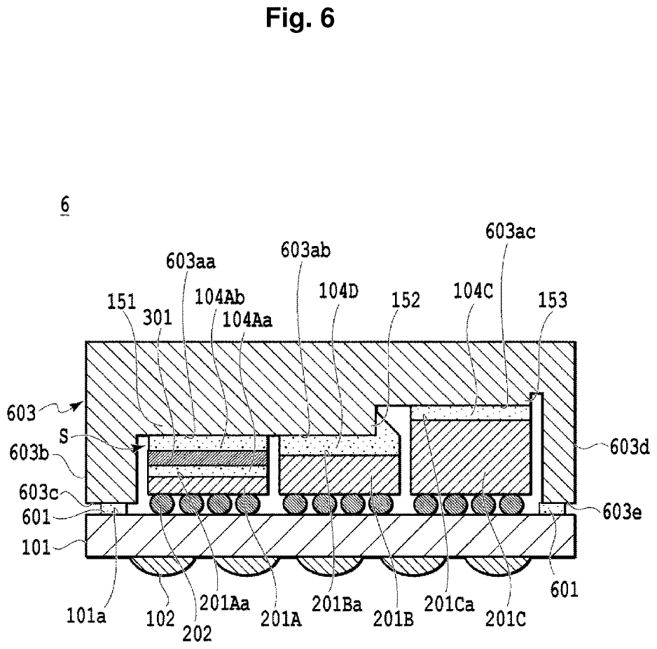

FIG. 6 is a cross-sectional view for describing a multi-chip optical module 6 according to a fifth embodiment. The multi-chip optical module 6 includes a substrate 101 and a lid component 603. The lid component 603 includes protrusions 151, 152, and 153 protruding toward the IC chips 201A, 201B, and 201C, respectively. A protruding facing surface 603aa of the protrusion 151 faces the IC chip 201A, a protruding facing surface 603ab of the protrusion 152 faces the IC chip 201B, and a protruding facing surface 603ac of the protrusion 153 faces the IC chip 201C. A series of side wall portions 603b and 603d are provided around the IC chips 201A, 201B, and 201C. A side wall facing surface 603c of the side wall portion 603b and a side wall facing surface 603e of the side wall portion 603d face the substrate 101. An adhesive layer 104Aa, a spacer 301, and an adhesive layer 104Ab are provided between the protruding facing surface 603aa and the chip facing surface 201Aa.

The fifth embodiment is different from the first embodiment and the like in that an adhesive layer 601 is also formed between the side wall portions 603b and 603d and the substrate 101, that is, the substrate 101 and the lid component 603 are adhered. The adhesive layer 601 corresponds to the second adhesive layer of the fifth embodiment. According to such a fifth embodiment, it is possible to compensate for a decrease in adhesive strength due to thinning of the adhesive layers 104Aa and 104Ab in consideration of the heat dissipation function. The side wall facing surfaces 603c and 603e are closer to the substrate 101 than the protruding facing surfaces 603aa, 603ab, and 603ac. Therefore, the interval between the lid component 603 and the substrate 101 is relatively narrow, and the thickness of the adhesive layer 601 can be set to a thickness that does not increase the temperature around the IC chip while compensating for the adhesive strength.

### Sixth Embodiment

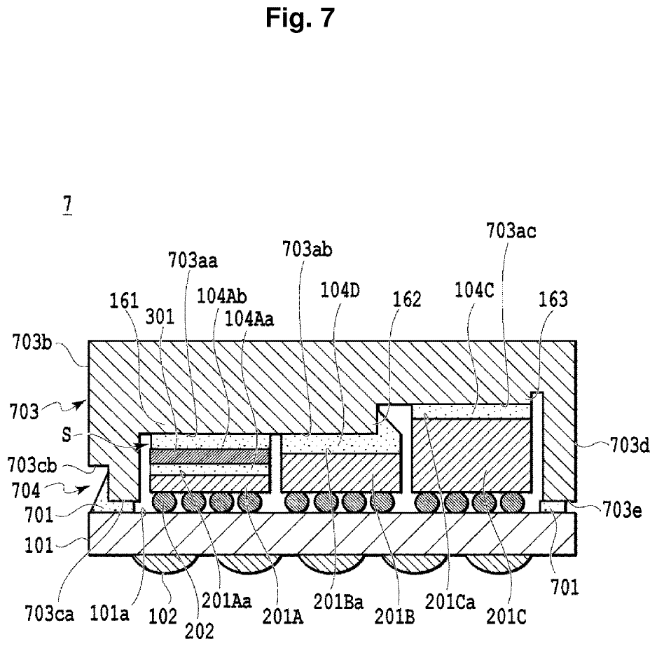

FIG. 7 is a cross-sectional view for describing a multi-chip optical module 7 according to a sixth embodiment. The multi-chip optical module 7 includes a substrate 101 and a lid component 703. The lid component 703 includes protrusions 161, 162, and 163 protruding toward the IC chips 201A, 201B, and 201C, respectively. A protruding facing surface 703aa of the protrusion 161 faces the IC chip 201A, a protruding facing surface 703ab of the protrusion 162 faces the IC chip 201B, and a protruding facing surface 703ac of the protrusion 163 faces the IC chip 201C. A series of side wall portions 703b and 703d are provided around the IC chips 201A, 201B, and 201C. Side wall facing surfaces 703ca and 703cb of the side wall portion 703b and a side wall facing surface 703e of the side wall portion 703d face the substrate 101.

In the sixth embodiment, at least a part of the side wall portions 703b and 703d includes a stepped portion 704 having a different distance from the substrate 101, and the stepped portion 704 is formed to be separated from the substrate 101 on a side farther from the protrusion 161 and the like than on a side closer to the protrusion 161 and the like. In other words, the stepped portion 704 is formed by the side wall facing surface 703cb that is far from the substrate 101 and the side wall facing surface 703ca that is closer to the substrate 101 than the side wall facing surface 703cb. That is, in the side wall portion 703b of the lid component 703, the side wall facing surface 703cb is separated from the substrate 101 outside the lid component 703. The adhesive that adheres the substrate 101 and the lid component 703 enters the stepped portion 704 to form a fillet. According to such a sixth embodiment, since the state of the adhesive layer 701 in the stepped portion 704 can be observed from the outside, the appearance inspection becomes easy.

### Seventh Embodiment

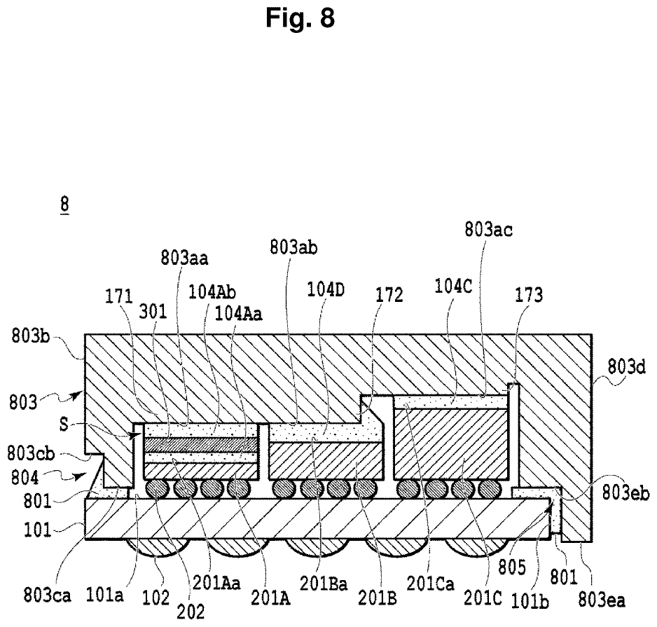

FIG. 8 is a cross-sectional view for describing a multi-chip optical module 8 according to a seventh embodiment. The multi-chip optical module 8 includes a substrate 101 and a lid component 803. The lid component 803 includes protrusions 171, 172, and 173 protruding toward the IC chips 201A, 201B, and 201C, respectively. A protruding facing surface 803aa of the protrusion 171 faces the IC chip 201A, a protruding facing surface 803ab of the protrusion 172 faces the IC chip 201B, and a protruding facing surface 803ac of the protrusion 173 faces the IC chip 201C. A series of side wall portions 803b and 803d are provided around the IC chips 201A, 201B, and 201C. Side wall facing surfaces 803ca and 803b of the side wall portion 803b face the substrate 101.

The side wall portion 803d includes a stepped portion 805 formed by lower surfaces 803ea and 803eb. An adhesive is applied between the stepped portion 805 and the substrate 101 to further form an adhesive layer 801 between a side surface 101b and a side wall portion 803ea of the substrate 101 in addition to the mounting surface 101a and the lower surface 803eb of the substrate 101. According to such a seventh embodiment, the strength of the package of the multi-chip optical module can be enhanced by increasing the adhesive area for adhering the lid component 803 and the substrate 101 while suppressing the thickness of the adhesive layer.

### Reference Signs List

1, 2, 3, 4, 5, 6, 7, 8 Multi-chip optical module
101 Substrate
101a Mounting surface
101b Side surface
102 External terminal
104A, 104B, 104C, 104D, 104Aa, 104Ab, 104Ac, 104Ad, 104Ae, 601, 701, 801 Adhesive layer
111, 112, 113, 121, 122, 123, 131, 132, 133, 141, 142, 143, 151, 152, 153, 161, 162, 163, 171, 172,
173 Protrusion
201A, 201B, 201C IC chip
201Aa, 201Ba, 201Ca Chip facing surface
202 Bump
203, 303, 403, 503, 603, 703, 803 Lid component
203aa, 203ab, 203ac, 303aa, 303ab, 303ac, 403aa, 403ab, 403ac, 503aa, 503ab, 503ac, 503ad, 503ae, 603aa, 603ab, 603ac, 703ab, 703ac, 803aa, 803ab Protruding facing surface
203b, 203d, 303b, 303d, 403b, 403d, 503b, 503d, 603b, 603d, 703b, 703d, 803b, 803d, 803ea Side wall portion
203c, 203e, 303c, 303e, 403c, 403e, 503c, 503e, 603c, 603e, 703c, 703e, 703ca, 703cb, 803c Side wall facing surface
203f Upper surface
301 Spacer
504, 505, 704, 805 Stepped portion
803ea, 803eb Lower surface
S Accommodation space

1. A multichip module in which a plurality of chip components mounted on one substrate are packaged, the multichip module comprising:
a lid component that forms an accommodation space for accommodating the plurality of chip components together with the substrate and has protrusions protruding toward each of the chip components; and
first adhesive layers formed between the protrusions and the chip components,
wherein protrusion lengths of the protrusions vary according to heights of the chip components with respect to the substrate.

2. The multichip module according to claim 1, wherein
the first adhesive layer between at least one of the chip components and the protrusion includes a spacer, and
a sum of thicknesses of the first adhesive layer including the spacer and the one chip component is equal to a sum of thicknesses of another one of the chip components and the first adhesive layer between the other one and the protrusion.

3. The multichip module according to claim 1, wherein an area of a protruding facing surface of the protrusion facing the chip component is smaller than an area of a chip facing surface of the chip component facing the protrusion.

4. The multichip module according to claim 1, wherein a protruding facing surface of the protrusion facing the chip component includes a stepped portion having a different protrusion length.

5. The multichip module according to claim 1, wherein
the lid component includes a side wall portion disposed around the protrusion,
the side wall portion includes a side wall facing surface facing the substrate,
the side wall facing surface is closer to the substrate than a protruding facing surface of the protrusion facing the substrate, and
a second adhesive layer is formed between the side wall facing surface and at least a part of the substrate.

6. The multichip module according to claim 5, wherein the second adhesive layer is further formed between a side surface of the substrate and the side wall portion.

7. The multichip module according to claim 5, wherein
at least a part of the side wall facing surface includes a stepped portion having a different distance from the substrate, and
the stepped portion is formed to be separated from the substrate on a side of the side wall facing surface that is farther from the protrusion than on a side closer to the protrusion.

8. The multichip module according to claim 1, wherein the lid component is at least partially made of metal.
